(19) United States
(12) Patent Application Publication
(10) Pub. No.: US 2012/0326033 A1
(43) Pub. Date: Dec. 27, 2012

(54) METHOD FOR SUPERIMPOSING AND DISPLAYING ELECTRON MICROSCOPE IMAGE AND OPTICAL IMAGE

(75) Inventors: Masamichi Shiono, Hitachinaka (JP); Masako Nishimura, Hitachinaka (JP)

(73) Assignee: HITACHI HIGH-TECHNOLOGIES CORPORATION, Tokyo (JP)

(21) Appl. No.: 13/580,576

(22) PCT Filed: Nov. 8, 2010
(86) PCT No.: PCT/JP2010/006529

§ 371 Date: Aug. 22, 2012

(30) Foreign Application Priority Data
Mar. 5, 2010 (JP) 2010-048561

(51) Int. Cl. H01J 37/26

(52) U.S. Cl. 250/310

(57) ABSTRACT

Firstly, displacement between an electron microscope image and an optical image is minimized; secondly, color information obtained by an optical image device having a digital picture function is added to an electron0 microscope image; and thirdly, a whole structure of equipment is simplified. The main character is that a mirror and backscattered electron detector is used and an electron beam to strike on a specimen and an optical axis from the optical image device coincide with each other. Addition of a function of an optical mirror to a backscattered electron detector permits a whole structure of equipment to be simplified, and a beam axis of an electron microscope and the optical axis of the optical image device to coincide with each other.

### TECHNICAL FIELD

The invention relates to a method for adding optical information due to visible light to an electron microscope image.

### BACKGROUND ART

An electron microscope has various advantages of resolution power, depth of focus, elementary analysis by an energy dispersive X-ray spectroscopy attached thereto and the like relative to an optical microscope. However, it has the greatest disadvantage that visible light information is not obtained by a general secondary electron detector or a backscattered electron detector. Accordingly, the electron microscope image lacks color information from visible light. Analysis under the electron microscope is essential for an investigation into the cause of a coloring phenomenon that is indentified on the surfaces of a piece of paper, a resinous film, a ceramic, a metal and a food under visual light, and for an investigation into the cause of damage on the surface of a product that visually deteriorates quality of the product. However, it is difficult to specify the position of the optical defect portion under the electron microscope.

Accordingly, for obtaining an optical microscope image at the observation position of the electron microscope, a mechanism for incorporating an optical microscope into the electron microscope has conventionally been invented. For example, Patent Document 1 (Japanese Patent Application Laid-Open NO. Hei 11-185682) discloses an electron microscope including, at the upper portion of an electron optical lens barrel, an optical microscope in which an aperture member for an electron beam to pass therethrough has an orifice composed of a transparent material, thereby sufficiently illuminating an observation specimen. Patent Document 2 (Japanese Patent Application Laid-Open NO. 2004-319518) discloses an electron microscope which includes a long focus microscope having an optical axis crossing the optical axis of an electron beam, and which constructs a long focus microscope coinciding with the electron microscope in the direction of moving visual field, thereby enabling an optical image having the same visual field as that of the electron microscope to be obtained. Patent Document 3 (Japanese Patent Application Laid-Open NO. Hei 11-96956) discloses an electron microscope in which a detection surface for reflected electrons is machined to a concave mirror, a cathode luminescence detector is located at the focus of the concave mirror, and thereby the backscattered electron detector and the cathode luminescence detector are integrally constructed. This construction enables both the images to be simultaneously observed without putting in and out the detector.

### PRIOR ART DOCUMENT

### Patent Document

Patent Document 1: Patent Application Laid-Open NO. HEI 11-185682

Patent Document 2: Patent Application Laid-Open NO. 2004-319518

Patent Document 3: NO. HEI 11-96956

### SUMMARY OF THE INVENTION

Technical Subject

The above-described techniques have the following problems. In the case of the invention described in Patent Document 1, all of orifices located on the optical axis of the electron microscope are required to be composed of a transparent material, which requires significant modification of the electron optical lens barrel. In the case of the invention described in Patent Document 2, the optical microscope and the electron microscope does not strictly coincide with each other in a direction of observation, which makes it impossible for the optical microscope image and the electron microscope image to be observed in the same visual field. In the case of the invention described in Patent Document 3, the detection surface of the backscattered electron detector is required to be machined to a concave mirror, and the mechanism becomes complicated as well as Patent Document 1. An optical image obtained is a cathode luminescence image and is not an optical scope image.

Accordingly, the present embodiment is directed to achievement of an electron microscope which prevents a displacement between visual fields of an electron microscope image and an optical microscope image to the minimum, with a simple configuration, without complicating a whole structure of equipment.

### Solution to Subject

A mirror located on an optical path is constructed integrally with a backscattered electron detector, and the backscattered electron detector is located below an objective lens, which thereby solves the conventional subject. Addition of a function of an optical mirror to the backscattered electron detector permits a whole structure of equipment to be simplified, and a beam axis of the electron microscope and an optical axis of an optical image device to coincide with each other

### Advantageous Effects of Invention

The method for superimposing and displaying the electron microscope image and the optical image according to the present embodiment minimizes displacement between visual fields of the electron microscope image and the optical image, and achieves a method for adding color information, obtained by the optical image device having a digital picture function, to the optical image without damaging property of the electron microscope image. This enables various optical defects to be analyzed under the electron microscope.

Specially, the method has effect on elementary analysis of foreign matters in a transparent film, on investigation into the cause of coloring phenomenon that is indentified on the surfaces of a piece of paper, a resinous film, a ceramic, a metal and a food under visual light and the quality control, and on investigation into the cause of damage on the surface of a product that visually deteriorates quality of the product and the quality control.

### BRIEF DESCRIPTION OF DRAWINGS

FIG. 1 is a side view of a backscattered electron detector of an embodiment 1.

FIG. 2 is an upper view which shows a positional relationship of an optical image imaging device, an energy dispersive X-ray spectroscopy and an illumination device for obtaining a shaded image relative to a specimen holder in an electron microscope of the embodiment 1.

FIG. 3 is a whole configuration view of the electron microscope of the embodiment 1.

FIG. 4 is an explanation view of the situation, as viewed from the optical image imaging device, where a specimen is projected on the mirror surface of the mirror and backscattered electron detector in the electron microscope of the embodiment 1.

FIG. 5 is an explanation view showing the procedure for obtaining a composite image of an electron microscope image and an optical image in the embodiment 1.

FIG. 6 is an explanation view showing a layout of a navigation window.

FIG. 7 is an explanation view showing a layout of the navigation window after an electron microscope image is obtained.

FIG. 8 is an explanation view where an electron microscope image and an optical image, displayed on the navigation window, are displaced from each other.

FIG. 9 is an explanation view showing a layout of an alignment window.

FIG. 10 is an example of an observation image obtained using an electron microscope of an embodiment 2 (state where a portion of a foreign matter is exposed from a film).

FIG. 11 is a side view of a backscattered electron detector of an embodiment 5.

FIG. 12 is an upper view which shows a positional relationship of an optical image imaging device, an energy dispersive X-ray spectroscopy and an illumination device for obtaining a shaded image relative to a specimen holder in an electron microscope of the embodiment 5.

FIG. 13 is an explanation view of the situation, as viewed from the optical image imaging device, where a specimen is projected on the mirror surface of the mirror and backscattered electron detector in the electron microscope of the embodiment 5.

FIG. 14 is an explanation view showing a layout of a navigation window in the electron microscope of the embodiment 5.

FIG. 15 is a side view of a backscattered electron detector of an embodiment 6.

FIG. 16 is an upper view which shows a positional relationship of an optical image imaging device, an energy dispersive X-ray spectroscopy and an illumination device for obtaining a shaded image relative to a specimen holder in an electron microscope of the embodiment 6.

### DESCRIPTION OF EMBODIMENTS

Hereafter, each embodiment of the present invention will be described with reference to the drawings.

### Embodiment 1

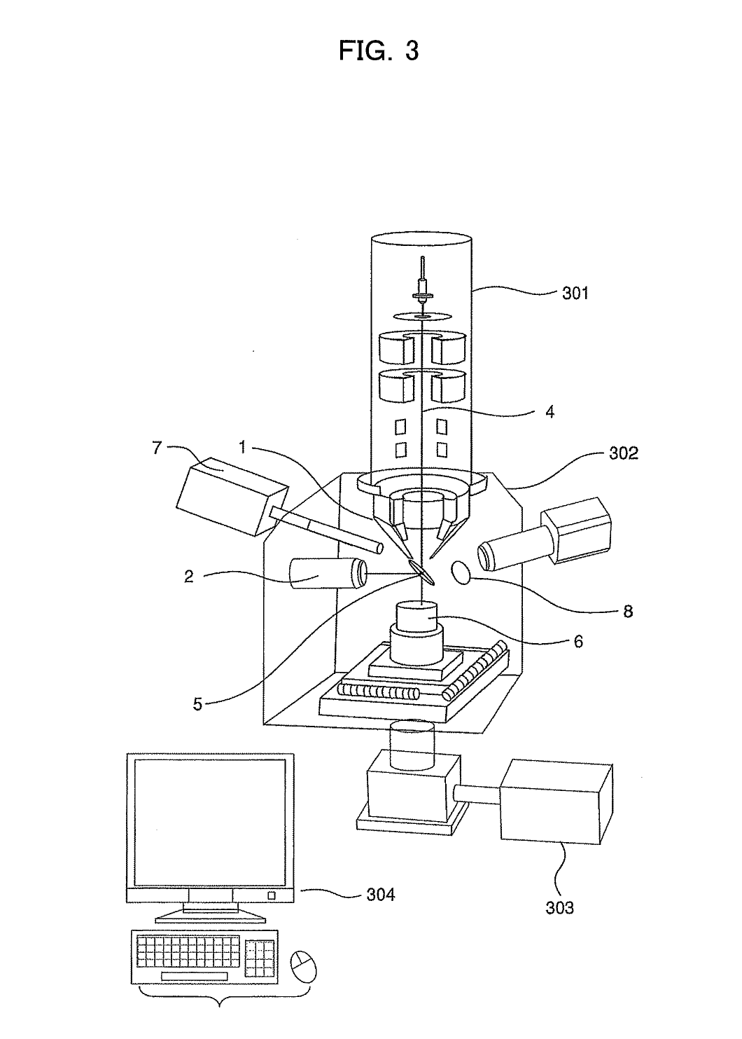

FIG. 3 shows a whole configuration view of an electron microscope of the present embodiment. The electron microscope of the present embodiment is constructed, generally, with an electron optical lens barrel 301 for scanning an electron beam on an observation specimen, a vacuum specimen chamber 302 for housing a specimen holder 6, an evacuation device 303 for evacuating the inside of the vacuum specimen chamber 302, a personal computer 304 including a display for displaying a obtained observation image, and the like.

The electron optical lens barrel 301 has an lower portion provided with an electron microscope objective lens 1, through which an electron beam, emitted from the electron gun, converges on a specimen. The vacuum specimen chamber 302 has an optical image imaging device 2, an energy dispersive X-ray spectroscopy 7, an illumination device for obtaining shaded image 8 and the like installed therein. The personal computer 304 also serves as a user interface for setting and inputting necessary information to control the operation of the equipment, and displays a GUI screen for inputting various setting information on the screen. In addition, the personal computer 304 also serves as an image processor which performs various image processings on an electron microscope image and an optical image obtained. It is noted that FIG. 3 is an example of a layout, and, in addition to the backscattered electron detector, a secondary electron detector or a low-vacuum secondary electron detector may be installed.

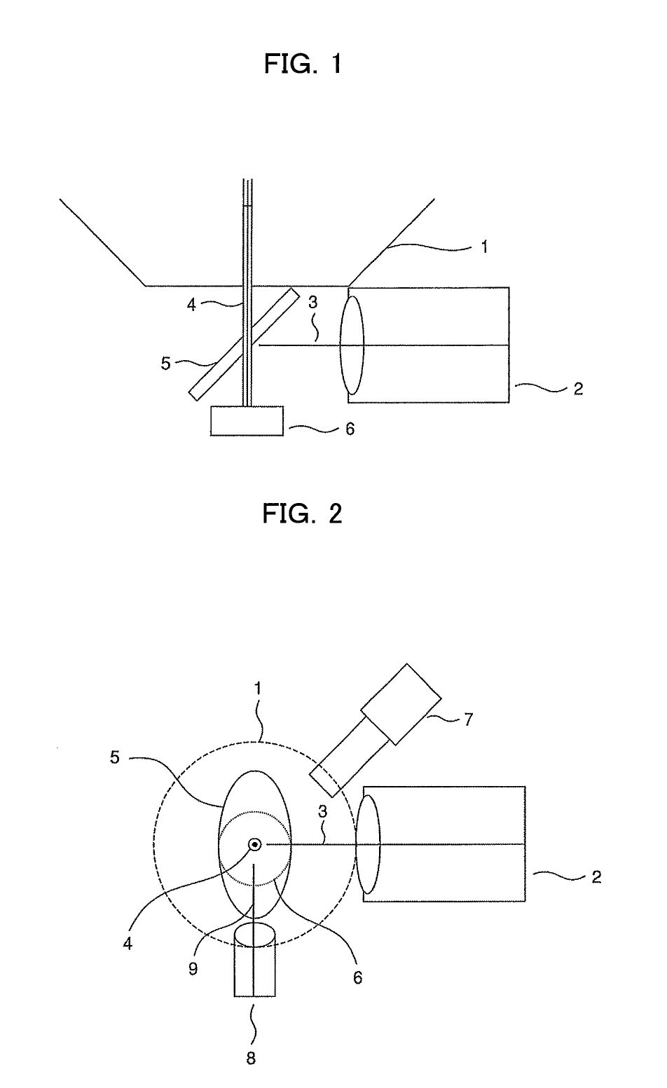

FIG. 1 is a side view of the backscattered electron detector of the embodiment 1. The numeral 1 denotes an electron microscope objective lens. The numeral 2 denotes an optical image imaging device having a digital picture function and an illumination function coaxial with the optical axis. The numeral 3 denotes the optical axis of the optical image imaging device. The numeral 4 denotes the optical axis of the electron microscope. The numeral 5 is a mirror and backscattered electron detector. The numeral 6 is a specimen holder.

The electron microscope is a scanning electron microscope, and desirably has a low vacuum observation function to enable observation on a specimen without vapor deposition. The reason for non-vapor-deposition observation being needed is because performing vapor deposition process causes color information under visual light, inherently owned by a specimen, to be lost. Although the electron gun is desirably a device having a filament of tungsten, it is not limited to this. Although the electron microscope is essential to have a mirror and backscattered electron detector, it may have or may not have the secondary electron detector. Although the energy dispersive X-ray spectroscopy is not always essential, it is desirably attached.

The optical image imaging device 2 includes a digital camera, a video camera having a digital output function and a CCD camera. In addition, it may include an optical device having a digital output function, and is not limited to the digital camera, the video camera or the CCD camera. The optical image imaging device enables obtaining a moving image and a still image, and it is desirable that optical image imaging device has effective pixels of 40 million or more and approaches a specimen at a distance of 3 cm to take an image.

The mirror and backscattered electron detector 5 has an undersurface constructing a reflection mirror which reflects illumination light from the optical image imaging device 2 toward a specimen and reflects the reflection light from the specimen toward the optical image imaging device 2. Simultaneously, this undersurface constructs a semiconductor backscattered electron detector having a detector surface of a mirror surface for detecting reflection electrons from the specimen. Further, to increase reflection efficiency of visual light, the undersurface may have vapor deposition applied thereto by use of aluminum.

The mirror and backscattered electron detector has a central portion having an aperture open through which an electron beam is radiated on the specimen 6. The optical axis 3 of the optical image imaging device makes an angle of 45 degree with the mirror surface of the mirror and backscattered electron detector. The optical axis of the electron microscope 4 also makes an angle of 45 degree with the mirror surface of the mirror and backscattered electron detector. The mirror and backscattered electron detector 5 has a function of detecting reflection electrons from the specimen, and has a function of reflecting an optical image of the specimen under visual light to send the optical image to the optical image imaging device 2. The mirror and backscattered electron detector desirably has a diameter of 30 mm or more, being not limited to it. The aperture at the central portion of the mirror and backscattered electron detector desirably has a diameter of 5 mm or less

The specimen holder 6 enables the horizontal position to be mechanically moved by motor driving or manual operation. Regardless of the motor driving and the manual operation, the specimen is desirably moved in a tilt, rotational, or vertical direction.

FIG. 2 is an upper view of a relative positional relationship of the optical image imaging device, the energy dispersive X-ray spectroscopy and the illumination device for obtaining shaded image according to the present embodiment relative to the specimen holder 6. The numeral 1 denotes the outline of the bottom surface of the electron microscope objective lens. The numeral 2 denotes an optical image imaging device including a digital picture function and an illumination function coaxial with the optical axis. The numeral 3 denotes the optical axis of the optical image imaging device. The numeral 4 denotes the optical axis of the electron microscope. The numeral 5 denotes a mirror and backscattered electron detector. The numeral 6 denotes a specimen holder. The numeral 7 denotes an energy dispersive X-ray spectroscopy. The numeral 8 denotes an illumination device for obtaining shaded image. The numeral 9 denotes the optical axis of the illumination device for obtaining shaded image.

The energy dispersive X-ray spectroscopy as denoted by the numeral 7 is used for analysis of element composition of a specimen. The specific procedure for use will be explained in an embodiment 2. Where a specimen having a concave and convex, for example, a damage, a hole or an attachment on the surface of the specimen is observed, it is difficult for the illumination device coaxial with the optical axis of the digital picture device to add shade to the concave and convex of the specimen, and the illumination device is used in a side direction as denoted by the numeral 8. Regarding the illumination device in the side direction, the specific usage is explained in the embodiment 4.

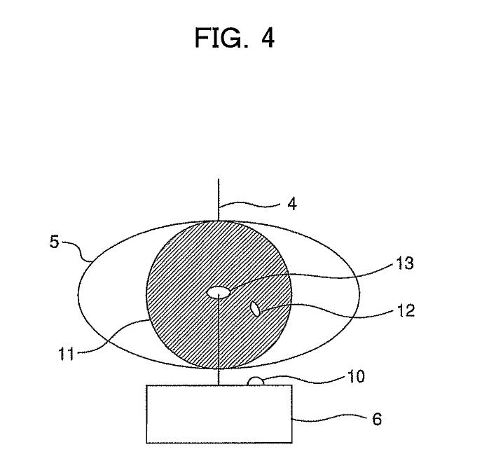

FIG. 4 is an explanation view of a situation where a specimen is projected on the mirror surface of the mirror and backscattered electron detector using the configuration of FIG. 1, as viewed from the optical image imaging device. The numeral 4 denotes the optical axis of the electron microscope. The numeral 5 denotes a mirror and backscattered electron detector. The numeral 6 denotes a specimen holder for the electron microscope. The numeral 10 denotes a sample on the specimen holder. The numeral 11 denotes the outline of the specimen holder 6 which reflects on the mirror and backscattered electron detector. The numeral 12 denotes a sample on the specimen holder, which reflects on the mirror and backscattered electron detector. The numeral 13 denotes an aperture at the central portion of the mirror and backscattered electron detector.

As shown in FIG. 4, the mirror and backscattered electron detector, as viewed from the optical image imaging device, has an aspect ratio of 1:2, while the specimen holder has an aspect ratio of 1:1, and no distortion occurs.

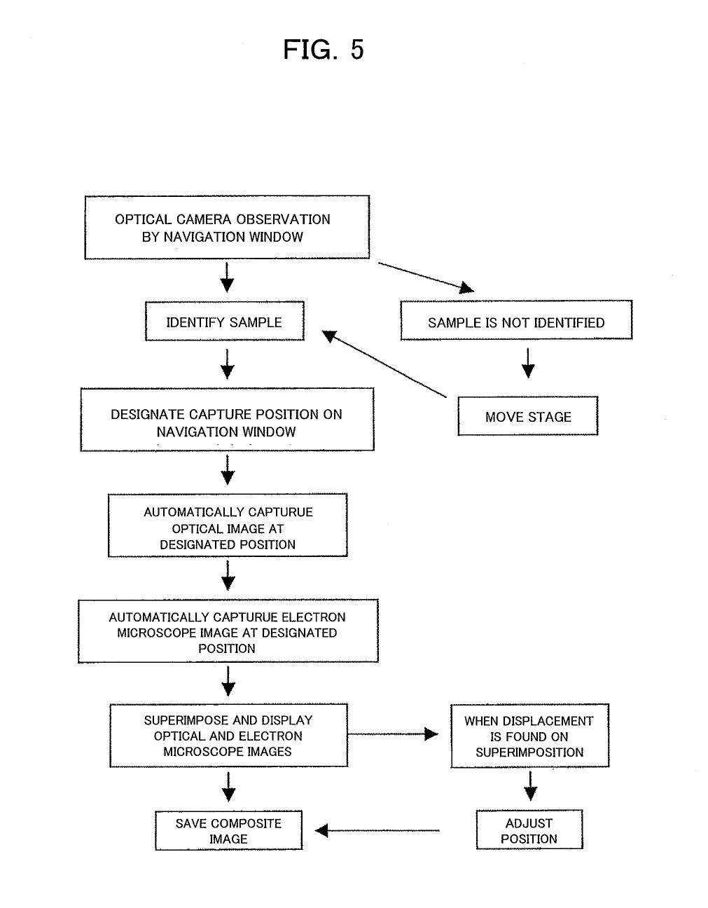

FIG. 5 is an explanation view which shows a procedure for obtaining a composite image of an electron microscope image and an optical image. An operator puts, into a specimen chamber of the electron microscope, a specimen of which the operator will obtain a composite image of an electron microscope image and an optical image. The operator vacuums the specimen chamber to start up a navigation window. The navigation window includes an image window section having a function of displaying an optical image, an electron microscope image and a composite image. The navigation window includes an operation window section where the operation procedure is arranged as a flowchart form. The navigation window is operated by a mouse and is displayed by use of a monitor capable of color display.

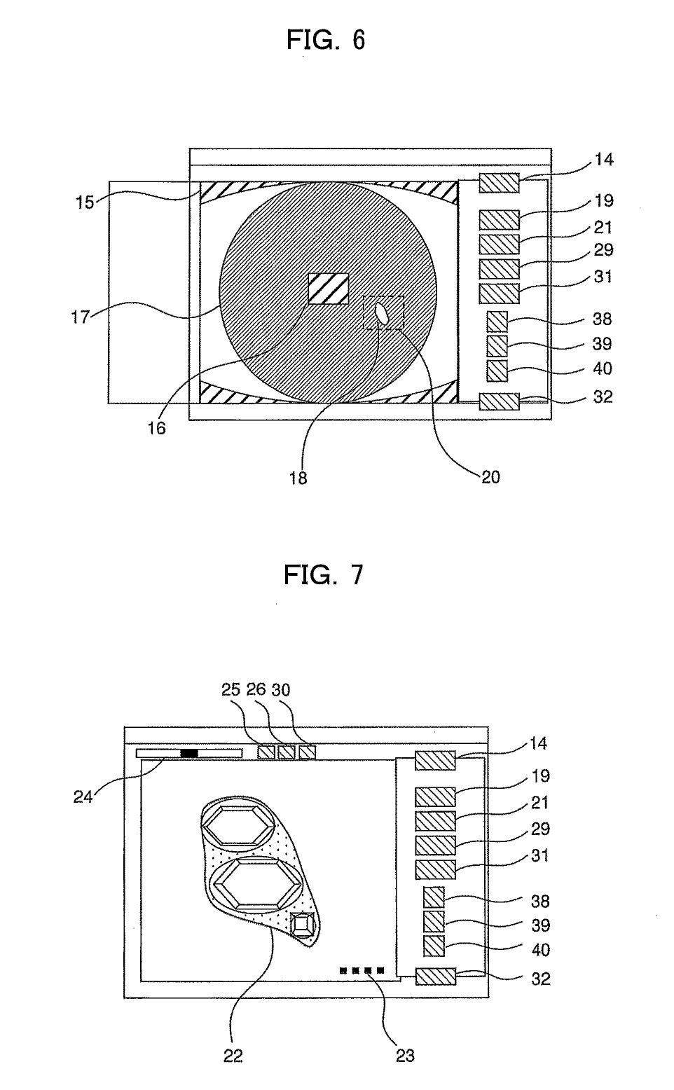

FIG. 6 is an explanation view showing a layout of the navigation window. When the start button as denoted by the numeral 14 in FIG. 6 is pressed, the image window 15 in FIG. 6 displays an optical image of the specimen holder. Although the displayed image is similar to that under the situation where the specimen holder is projected on the mirror and backscattered electron detector as shown in FIG. 4, the image displayed on the window has been subjected to a mirror image correction. When the whole area of the optical reflection image, projected on the mirror and backscattered electron detector, is displayed on the image window, the image is laterally elongated. Therefore, as shown in FIG. 6, the left portion and the right portion of the optical reflection image may be trimmed. The mirror and backscattered electron detector has a central portion having an aperture open for an electron beam to pass therethrough. As denoted by the numeral 16 in FIG. 6, a digital processing for covering the aperture may be applied.

In FIG. 6, the image window 15 displays a whole area image of the specimen holder of the electron microscope, as denoted by the numeral 17, and an optical image of the sample on the specimen holder, as denoted by the numeral 18. The optical image is desirably a moving image. As shown in FIG. 6, if the operator identifies a sample, which the operator will observe, on the image window, there are not any problems. While, if the sample is located at the central portion of the specimen holder, it is covered with the digital processing as denoted by the numeral 16 in FIG. 6. In this case, the operator clicks a visual field click button 19 in FIG. 6, which permits the specimen holder to horizontally move by about 5 mm by use of motor driving. On the other hand, manual operation may permit the specimen holder to be mechanically moved. In this case, the moving direction is enabled to be along either X axis or Y axis. The distance of horizontal movement may be 5 mm or more or 5 mm or less, if the position that the operator will observe is located outside the region for the digital processing, as denoted by the numeral 16.

After the operator identifies the sample on the image window, the capture position selection tool, as denoted by the numeral 20 in FIG. 6, encloses the position at which the operator will obtain a composite image. The capture selection tool is displayed by a rectangle having an aspect ratio of 3:4. Drag-and-drop operation of the mouse on the window permits the start point and the finish point to be designated. The operator designates the position that the operator will obtain the composite image by the use of the capture position selection tool, and clicks the capture position decision button as denoted by the numeral 21 in FIG. 6.

In the case of the electron microscope of the embodiment, when the capture position decision button 21 is clicked, the optical still image is automatically captured. After the capturing, illumination for optics is automatically turned off. Next, the electron microscope image at the designated position is obtained. This series of operations is desirably performed automatically.

After the optical image is captured as the still image, only the region, designated by the operator by use of the drag-and-drop operation, is cut out from the whole area image of the specimen holder which is projected on the mirror and backscattered electron detector. This cut-out image region is converted into a pixel image of vertical 640 pixels and horizontal 480 pixels or a pixel image of vertical 1280 pixels and horizontal 960 pixels by digital conversion. However, an optical image imaging device, having a zoom function attached therewith, may capture only the position designated by the operator. If a displacement from the electron microscope image is a problem, it is necessary to cut out an image including the periphery portion outside the designated position of the optical image. If the displacement tolerance of 10% is needed, the image is converted to a pixel image of vertical 704 pixels and horizontal 528 pixels or a pixel image of vertical 1408 pixels and horizontal 1056 pixels.

The electron microscope is also captured with vertical 640 pixels and horizontal 480 pixels or vertical 1280 pixels and horizontal 960 pixels. Immediately before the capturing, operations of autofocus and auto-brightness and contrast are desirably performed automatically. Although capture time of 40 seconds or 80 seconds is standard, it is desirable to be arbitrarily set in accordance with needs.

FIG. 7 is an explanation view showing a navigation window after an operator clicks the capture position decision button 21. Practically, after the capture position decision button is clicked, captures of the optical image and the electron microscope image are performed. Therefore, transition to the state of FIG. 7 from clicking of the capture position decision button by the operator requires a time of about one or two minutes. At this time, processing situation of the image is displayed on the image window, reducing stress on the operator.

In FIG. 7, the numeral 22 denotes a composite image of an electron microscope image and an optical image, which is displayed on the image window. The numeral 23 denotes a scale bar. Other than this, magnification at the obtaining of an image may be displayed. The composite image has the optical image for which an opacity is set to 70%, and is displayed by superimposing the optical image on the electron microscope image. Here, the opacity is explained. An opacity of 0% is a state where the under-image is completely visible, and if an opacity is set to 100%, the under-image is completely invisible. Accordingly, an opacity of 70% is a state where the optical image is dominantly visible, which enables only a distinctive structure having a strong contrast in the electron microscope image to be visible.

At this time, the operator confirms whether the electron microscope image and the optical image are completely superimposed using a distinctive structure as a mark on the image. Depending on a sample, the optical image is required to become more dominant, or, on the contrary, there is a case where the electron microscope image is required to become dominant. At this time, an opacity setting bar 24 in FIG. 7 is used to adjust opacity of the optical image to any value. It is desirable for the opacity of the optical image to be arbitrarily changed from 0% to 100%

The optical image having an opacity of 0% enables only the electron microscope image to be displayed. At this time, if the focus, the brightness, or the contrast is inadequate, the electron microscope image may be adjusted. Normally, when detailed image adjustment of the electron microscope image is performed, a small sized image is generally used. On the other hand, in the configuration of the present embodiment, clicking a small sized image switch button 25 in FIG. 7 enables a present screen to be switched into a small sized image. In a state of FIG. 7, the electron microscope image is displayed as a still image. While, when the small sized image switch button 25 in FIG. 7 is clicked, an image of live time is displayed on the small sized image. After the focus, the brightness and the contrast are adjusted, clicking the small sized image switch button 25 again permits the electron microscope image to be captured for transiting into a still image. At this time, if the electron microscope image is displayed not by the small sized image but by the full screen of the image window as a live time image, for example, clicking the live image switch button 26 in FIG. 7 permits the electron microscope image to be transited into the live time image with the electron microscope image displayed on the image window by the full screen.

If focus, brightness and contrast are manually adjusted, a mouse operation may permit the image to be adjusted, or an operation tab such as an encoder may be used to mechanically adjust the image. If the mouse operation permits focus, brightness and contrast to be adjusted, an adjustment bar may be displayed on the image window. Regarding the astigmatism adjustment, in the same way, mouse operation may perform adjustment, or an operation tab may be used to manually adjust the image.

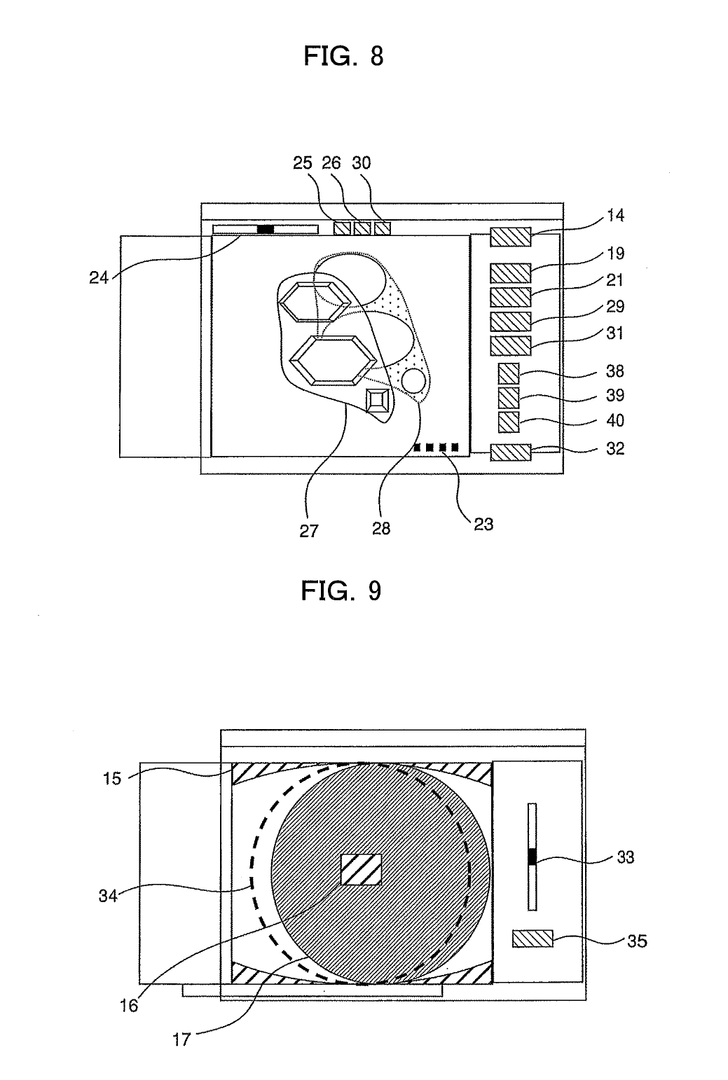

FIG. 8 is an explanation view of the case where displacement between the display positions of an electron microscope image and an optical image is visible. In FIG. 8, the numeral 27 denotes an electron microscope image, and the numeral 28 denotes an optical image. If the optical image is aligned with the electron image by drag-and-drop operation of the mouse, both distinctive structures visible on the optical image and the electron image are allowed to coincide in position with each other for transiting into the state as shown in FIG. 7. At this time, what moves by the drag-and-drop operation is the optical image, and the electron microscope image is fixed on the image window. At this time, if the optical image of the same area as that of the electron microscope image is cut out, movement of the optical image causes a non-displayed portion of the optical image. However, if the optical image previously obtains a margin more widely than a display area of the electron microscope image, movement of the optical image does not cause the non-display portion of the optical image to appear. When the drag-and-drop operation of the optical image is performed, the opacity setting bar as denoted by the numeral 24 in FIG. 7 is used to enable the opacity of the optical image to be arbitrary adjusted.

If the display positions of the electron microscope image and the optical image aligned and the focus, brightness and contrast on the electron microscope image are adequately adjusted, clicking the save button for a composite image as denoted by the numeral 29 permits the image to be saved. In this case, the opacity of the optical image is automatically set to 45%. The opacity of 45% shows a state of the electron microscope image being dominant. This enables optical information to be added to the electron microscope image, without impairing property of the electron microscope image such as high resolution power or deep depth of focus. This opacity, however, is not limited to 45%, and is desirable to be changed to any value in setting. When the composite image is saved, not only the opacity is changed, but also it is desirable to perform automatic level adjustment or automatic contrast adjustment of the composite image. Saturation may be emphasized if necessary.

It is possible to save the composite image of the electron microscope image and the optical image by any format of JPEG, TIFF and BMP. The saved image is browsable by opening the file of the saved image. After the save button for the composite image as denoted by the numeral 29 in FIG. 7 is clicked, the image which is the same as the saved image is displayed on the image window, and the operator easily confirms that saved image does not have any problems. That is, the optical image in this state has an opacity of 45%.

If the saved image is inadequate, and adjustment of the display positions of the electron microscope image and the optical image or adjustment of the focus, brightness and contrast of the electron microscope image is performed again, the operator clicks a reset button 30 in FIG. 7. At this time, the opacity of the optical image is reset to 70%, and drag-and-drop operation enables the optical image to be arbitrarily moved.

If color information is unnecessary when only the electron microscope image is saved, the save button 31 for the electron microscope image in FIG. 7 is clicked. In this case, it is possible to save the electron microscope image by any format of JPEG, TIFF and BMP

If the saved image satisfies the operator and the operator will start to obtain an image of another sample, the operator clicks a start button, as denoted by the numeral 14 in FIG. 7, to start operation from the beginning. It is noted that the start button as denoted by the numeral 14 in FIG. 7 has the same layout as that of the start button as denoted by the numeral 14 in FIG. 6. The composite image of the electron microscope image and the optical image is identified in a visual field, and if observation of another sample starts without saving the composite image, the start button is clicked. That is, this start button functions as a reset button for starting operation from the beginning in all the procedure of image adjustment.

If the electron microscope image and the optical image always superimpose with an offset, alignment of the position of the specimen holder is required. When an alignment button as denoted by the numeral 32 in FIG. 7 is clicked, the alignment window in FIG. 9 is displayed. An operator uses a specimen holder size input tool 33 in FIG. 9 to select a size of the specimen holder which is put in the specimen chamber of the electron microscope at present. This selection changes the size of a circular specimen holder setting frame for alignment as denoted by 34 in FIG. 9. The operator mechanically moves the specimen holder or a stage having the specimen holder fixed thereto, to superimpose the outline of whole area image 17 of the upper surface of the specimen on the circular specimen holder setting frame for alignment as denoted by the numeral 34 in FIG. 9. This operation completes the alignment. After the alignment is completed, an alignment completion button as denoted by the numeral 35 in FIG. 9 is clicked to complete the operation. After the alignment completion button is clicked, the operation permits transition to the navigation window of FIG. 6. It is noted that an alignment button as denoted by the numeral 32 in FIG. 7 has the same layout as that of the alignment button as denoted by the numeral 32 in FIG. 6. That is, this alignment button functions as a button for starting to perform alignment in all the procedure of the image adjustment.

### Embodiment 2

Hereafter, the procedure is explained, in which a configuration of the embodiment obtains a composite image of an electron microscope image and an optical image corresponding to a foreign matter in a transparent film, and, in addition, performs the elemental analysis at the objective position by the energy dispersive X-ray spectroscopy. The foreign matter indicates a material included in a product without intention of a manufacturer of the product. The foreign matter is a particle or aggregation of particles mixed in the product to hinder the product from being shipped. Most of foreign matters have sizes identifiable under visual observation or an optical microscope. Most of transparent films are colorless and transparent resinous films, having various thicknesses. The configuration of this embodiment is applicable to evaluation of a foreign matter which exists in a piece of paper, a glass, an optically transparent mineral represented by mica, in addition to a resinous film.

A foreign matter contained in the transparent film has an optical image and an electron microscope image significantly different from each other in visual performance. The reason is because a whole image of the foreign matter is optically visible through the transparent film, while the film is opaque under the electron microscope, and only a portion of the foreign matter, which is exposed from the film, is observed.

When a foreign matter is found, an operator puts a film, containing the foreign matter, into the specimen chamber of the electron microscope to vacuum the specimen chamber and to start the navigation window. After the operator identifies a sample on the image window in which an optical image under a low magnification is displayed, the capture position selection tool as denoted by the numeral 20 in FIG. 6 encloses the foreign matter of which the operator will obtain the composite image. At this time, the image window displays the optical image, and the operator easily identifies the position of the foreign matter. Next, when the capture position decision button is clicked, the composite image of the optical image and the electron microscope image is displayed on the image window. The procedure up to here is the same as that of the embodiment 1.

If the electron microscope image is a reflection electron image, the foreign matter in the film is visible with the contrast different from that of a film portion. If the foreign matter is a metal or a metal compound, a portion with a contrast, which is brighter than the periphery, is observed. This portion is the foreign matter exposed from the film. If the outlines of foreign matters on the electron microscope image and the optical image superimpose on each other, the foreign matter is completely exposed from the film. On the other hand, if there are no positions which contrasts are different under the electron microscope, the foreign matter has the same composition as that of the film or is completely embedded in the film.

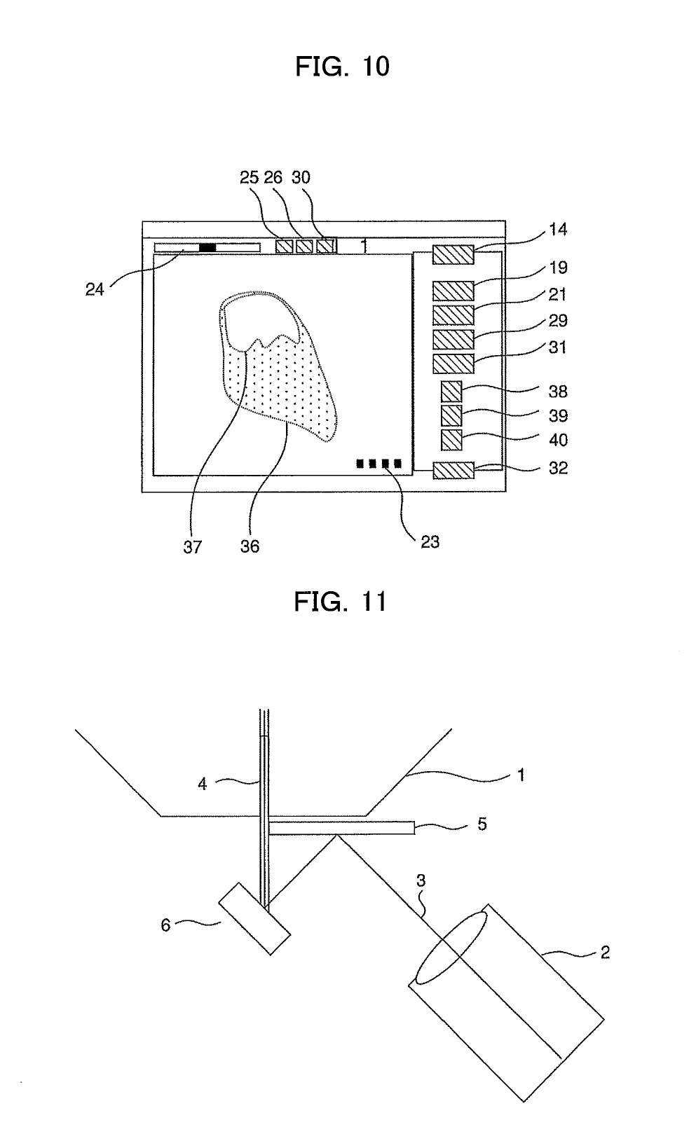

FIG. 10 is an explanation view of a state where a portion of a foreign matter, composed of a metal or a metal compound, is exposed from a film, and which is observed by the method of the embodiment. This corresponds to the state of FIG. 7 in the embodiment 1. The gray portion 36 in FIG. 10 is an optical image of the foreign matter, and the white portion 37 is an electron microscope image of the foreign matter. The electron microscope image of the foreign matter is desirably a reflection electron image. The portion exposed out of the film is visible with a bright contrast on the electron microscope image, while the portion of the foreign matter covered with a film component is visible with the same contrast as that of the film. While, on the optical image, the portion of the foreign matter covered with the film component is visible in the same way as that of the exposed portion. Therefore, if both the images superimpose on each other, the portion of the foreign matter, exposed from the film, is visible with a bright contrast, while the portion of the foreign matter covered with the film component is visible with a dark contrast.

If the portion of the foreign matter, exposed from the film, is emphatically displayed, the operator clicks a foreign matter mode button as denoted by the numeral 38 in FIG. 10. This operation permits the electron microscope image to be binarized into a bright contrast portion and a dark contrast portion, and the bright portion is displayed by a pseudo color. Namely, the foreign matter, exposed out of the film, is displayed by the pseudo color. The film portion and the portion of the foreign matter covered with the film component are black, causing image information to be lost. If an optical image having opacity set to 70% to 45% is superimposed on the electron microscope image to form a composite image, a portion of the foreign matter, exposed from the film, is displayed by the optical image and the electron microscope image colored by a pseudo color being superimposed on each other. The location where the foreign matter is embedded in the film is displayed by only the optical image.

This method has an advantage that an operator visually easily judges using a pseudo color where a portion of the foreign matter is , which is visible under the electron microscope and is exposed from the film, is positioned in the whole foreign matter. Namely, if the foreign matter is optically visible so as to be composed of a plurality of units, use of the method of the embodiment enables the operator to judge which unit is exposed out of the film.

As another application, the method enables an insulation failure location to be easily found on a sample having a conductive material such as a metal covered with a resin. Only the electron microscope image is observable to only the location having a resinous coat peeled off. While, the method of the embodiment finds a whole structure by the optical image, and, in addition, enables which portion has an insulation failure to be visually found. The insulation failure location is displayed in a pseudo color, while displaying of the location by a color significantly different from that of the sample is natural to be easily visible. Accordingly, the pseudo color display of the electron microscope image is desirably changeable into an arbitrary color.

The operator performs the composition analysis of the portion, displayed in a pseudo color, by the energy dispersive X-ray spectrometry and judges what the foreign matter is. In this case, the method of the embodiment has an advantage of visually judging which location in the whole foreign matter is analyzed. At this time, if the analysis is limited to the portion displayed by the pseudo color, the composition of the foreign matter is detected. Even if the foreign matter is visible on the optical image when the location, being not displayed in the pseudo color, is analyzed, a resinous component is detected. If a foreign matter is composed of a plural of units when most portions of the foreign matter is embedded in the film and only a portion thereof is observed under the electron microscope, the operator easily know which unit is analyzed using the method of the embodiment.

When the operator clicks an foreign matter mode button as denoted by the numeral 38 in FIG. 10, a mouse is enabled to designate any position. When the operator clicks a display button 39 for an energy-dispersive X-ray spectrometry result, the energy-dispersive X-ray spectrometry result is displayed. As a method for designating an arbitrary position, single-click or double-click on an objective position results in a point designation, and drug-and-drop operation results in an area designation. When a mapping start button as denoted by the numeral 40 in FIG. 10 is clicked, mapping analysis on the whole screen being displayed starts.

It is noted that a method for saving the composite image of the optical image and the electron microscope image is the same as that of the embodiment 1.

### Embodiment 3

Hereafter, a procedure is explained, in which a configuration of the embodiment obtains a composite image of an electron microscope image and an optical image corresponding to an optical color defect, and performs the elementary analysis on the objective position by the energy dispersive X-ray spectroscopy. The optical color defect is a coloring phenomenon that is identified on the surface of a piece of paper, a resinous film, a ceramics, a metal and a food under visual light, namely, under visual observation or an optical microscope. This optical color defect indicates a phenomenon that is not expected by a manufacturer and that is likely to be a problem for shipment of products. Colors formed in most of optical color defects result from accumulation of a foreign matter, impurities and a contamination that is not expected by a manufacturer. The phenomenon can be caused by accumulation of additives which are intentionally mixed by a manufacturer. In addition, there is a coloring phenomenon caused by deterioration of a basic product and machinery or chemical reaction, and this coloring phenomenon is synonymous with corrosion or rust. There is also a biological coloring phenomenon caused by growth of a microbe. In addition, the product has a thin layer of an oil or a resin appearing on the surface, which sometimes colors the surface of a specimen iridescent. A product has a surface having a smoothness disordered, which causes a coloring due to scattering of light to be sometimes visible. This phenomenon is synonymous with that of the embodiment 4.

Optical color defect caused by the coloring phenomenon is easily identified under visual observation or an optical microscope, while the identification under an electron microscope frequently causes an operator to be at a loss. This cause is because general secondary electron and backscattered electron detectors of the electron microscope do not detect visual light, and accordingly optical color is invisible. As a general example, if the surface of the machinery is colored red, blue or yellow when the colored location is identified under the electron microscope, it is difficult to judge which position on it is red, blue or yellow. With a few colored locations, drafting of a simple sketch enables the colored locations to be identified under the electron microscope. With a lot of colored locations, the identification is impossible. While, although it is difficult to identify optical color information under the electron microscope, composition image observation by use of a reflection electron image and elementary analysis by use of the energy dispersive X-ray spectrometry can become effective means for investigating into a cause of an optical color defect. Therefore, superimposing and displaying optical color information and an electron microscope image is an important subject, and the embodiment can be effective solving means for this subject.

When this optical color defect is found, an operator puts an film containing the optical color defect into the chamber of the electron microscope to vacuum the chamber to start the navigation window. The operator identifies the sample on the window, and thereafter encloses the optical color defect by the capture position selection tool as denoted by the numeral 20 in FIG. 6. At this time, the window displays an optical image, and the operator easily identifies the position of the optical color defect. Next, when the operator clicks the capture position decision button, a composite image of the optical image and the electron microscope image is displayed on the window. The procedure up to here is the same as that of the embodiment 1.

The operator is enabled to observe the electron microscope image having the optical color information added thereto, and easily identifies the structure identified under the electron microscope and the colored location. If the operator observes the reflection electron image when identifying difference of the contrast of the reflection electron image corresponding to the colored location, the operator judges a foreign matter being attached and having a composition other than that of the machinery. In this case, composition analysis by the energy dispersive X-ray spectrometry judges what the foreign matter is. If there are a lot of colored locations having various colors and the reflection microscope images have variously different contrasts, respectively, it is an effective means for solving the subject that the operator clicks the mapping start button 40 to obtain information of a two-dimensional element distribution.

### Embodiment 4

Hereafter, the procedure is explained, in which a configuration of the embodiment obtains a composite image of an electron microscope image and an optical image corresponding to a damage identifiable on the surface of a metal, a ceramics, a resin or a glass under visual observation or an optical microscope, and the energy dispersive X-ray spectroscopy performs the element analysis at an objective position. A damage is mostly concave as a point or a line shape, and includes occasionally a bulge. Herein, the phenomenon that appears on the surface of a product and disorders smoothness on the surface of the product without intent of a manufacturer of a product is called damage. Existence of the optically visual damage has a significant influence on quality of the product in sense of beauty and performance, and is a phenomenon that specially requires attention in the manufacturing floor. The method as explained herein is not limited to a metal, a ceramics, a resin or a glass, and is applicable to evaluation of the surface configurations of various organic and inorganic materials.

The damage is easily identified under visual observation or an optical microscope, however the position identification under the optical microscope frequently causes an operator to be at loss. This cause is because visual appearances of a concave and convex on the surface of a machinery under an electron microscope and visual observation or an optical microscope significantly differ therebetween, and the electron microscope enables various microstructures on the surface of the machinery to be identified, which rather causes the operator to be at a loss for specifying the optically identified damage.

If such a damage is found, the operator puts a sample having a damage optically visible into the chamber of the electron microscope to vacuum the chamber to start the navigation window. The operator identifies the sample on the image window, and thereafter encloses the optical color defect by the capture position selection tool as denoted by the numeral 20 in FIG. 6. At this time, the window displays an optical image, and the operator easily identifies the position of the damage. Next, when the operator clicks the capture position decision button, a composite image of the optical image and the electron microscope image is displayed on the window. The procedure up to here is the same as that of the embodiment 1.

The operator is enabled to observe the electron microscope image having the optical color information added thereto, and easily identifies the structure identified under the electron microscope and the damage of the problem. If the operator observes the reflection electron image when identifying a difference of the contrast of the reflection electron image corresponding to the position of the damage, the operator decides that a foreign matter is attached and has a composition other than that of the machinery. In this case, as shown by the embodiment 2, composition analysis by the energy dispersive X-ray spectrometry permits the causative matter in the foreign matter causing the damage to be decided. While, if the operator observes by use of a secondary electron, the operator is specifically observable to the structure of the damage.

If the optical image imaging device with an illumination function and a light source are coaxial with each other, it is difficult to see a shade caused by a concave portion and a convex portion and add a light and darkness to the damage on the surface of a specimen. In this case, an illumination device for obtaining shaded image as denoted by the numeral 8 in FIG. 2 is utilized. Namely, the axes of the image imaging device and the light source are changed to emphasize the shade. If angle of the specimen illuminated by the illumination device is changed, the specimen holder stage is rotated to correspond to this.

### Embodiment 5

In the embodiment 1, as shown in FIG. 1, the mirror and backscattered electron detector having an aperture open through the central portion is obliquely disposed making a tilt angle of 45 degree with the optical axis of the electron microscope directly below the electron microscope objective lens, while a location manner as shown in FIG. 11 may be adopted. Namely, this manner is such a way that the mirror and backscattered electron detector is horizontally displaced from the position directly below the objective lens of the electron microscope, which eliminates the aperture at the central portion of the mirror and backscattered electron detector. It is noted that in the electron microscope of the embodiment, components other than the construction as shown in FIG. 11 are the same as those in FIG. 3.

In the method as shown in FIG. 11, the mirror surface of the mirror and backscattered electron detector is disposed making a right angle with the optical axis of the electron microscope. The mirror and backscattered electron detector is desirably a semiconductor backscattered electron detector. The detection surface for a reflection electron is composed of a mirror surface, and vapor deposition with aluminum may be applied to the detection surface to increase reflection efficiency of visual light. In the configuration of the invention, an electron beam passes outside the mirror and backscattered electron detector. Accordingly, the mirror and backscattered electron detector is horizontally displaced to be kept away from the central portion of the objective lens of the electron microscope.

In FIG. 11, the optical image imaging device 2 including a digital picture function and an illumination function coaxial with the optical axis is located diagonally below the mirror and backscattered electron detector. The optical axis 4 of the optical image imaging device is disposed making an angle of 45 degree with the optical axis of the mirror and backscattered electron detector. The specimen holder as denoted by the numeral 6 is disposed in such a manner that the top surface makes an angle of 45 degree with the optical axis of the optical electron microscope.

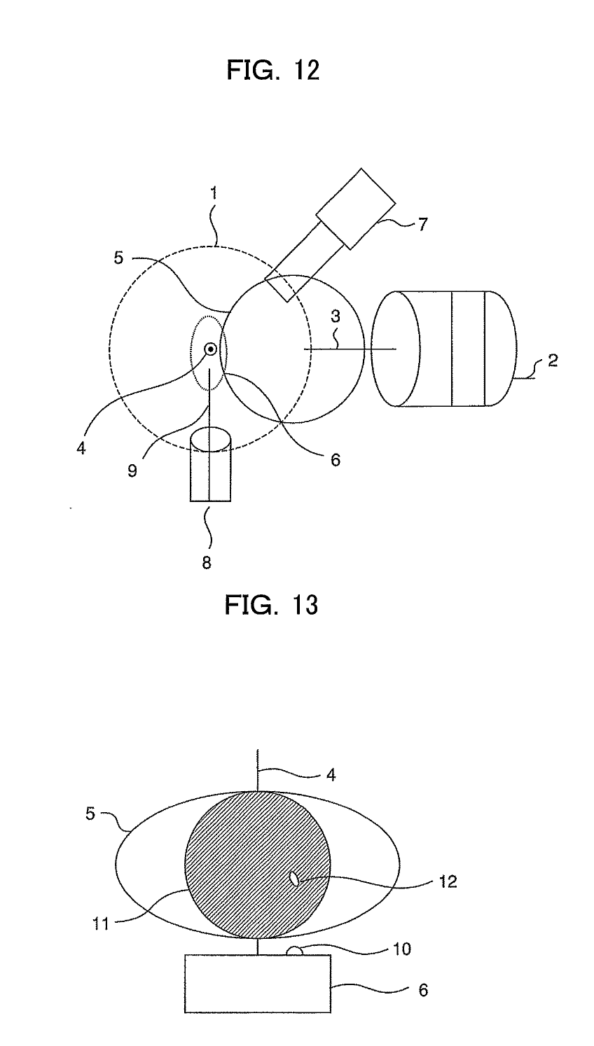

FIG. 12 is an explanation view of the embodiment as shown from the upward, in which the mirror and backscattered electron detector is horizontally offset from the position that is directly below the objective lens of the electron microscope. The energy dispersive X-ray spectroscopy as denoted by the numeral 7 is used for analysis of element composition of a sample. The specific procedure for use is explained in the embodiment 2. If a sample having a concave and convex, for example, a damage, a hole and an attached matter on the surface of the sample is observed, an illumination device coaxial with the optical axis of the digital picture device is difficult to add a shade to the concave and convex of the specimen. Therefore, as shown in FIG. 8, the illumination device is used in a side direction.

As shown in FIG. 13, as viewed from the optical image imaging device, the mirror and backscattered electron detector has an aspect ratio of 1:2, while the specimen holder has an aspect ratio of 1:1, and no distortion occurs. The mirror and backscattered electron detector desirably has a diameter of 30 mm or more. This configuration has an advantage that the mirror and backscattered electron detector does not have any apertures at the central portion. Accordingly, the sample is enabled to be projected on the central portion of the mirror and backscattered electron detector.

In the configuration of the invention, the specific procedure for use is the same as those of the embodiments 1, 2, 3 and 4. While, the sample is enabled to be projected on the central portion of the mirror and backscattered electron detector, which eliminates the necessity of a digital processing for covering the aperture as denoted by the numeral 16 in FIG. 6. FIG. 14 is an explanation view showing a layout of the navigation window in the configuration of the invention. In the embodiment 1, if a sample is located at the central portion of the sample holder, an operator is required to click a visual field moving button 19 in FIG. 6 to horizontally move the specimen by about 5 mm by use of motor driving. However, in the embodiment in which the mirror and backscattered electron detector is horizontally offset from the position being directly below the objective lens of the electron microscope, this operation is unnecessary. Operation procedure other than this is the same as those of the embodiments 1, 2, 3 and 4.

### Embodiment 6

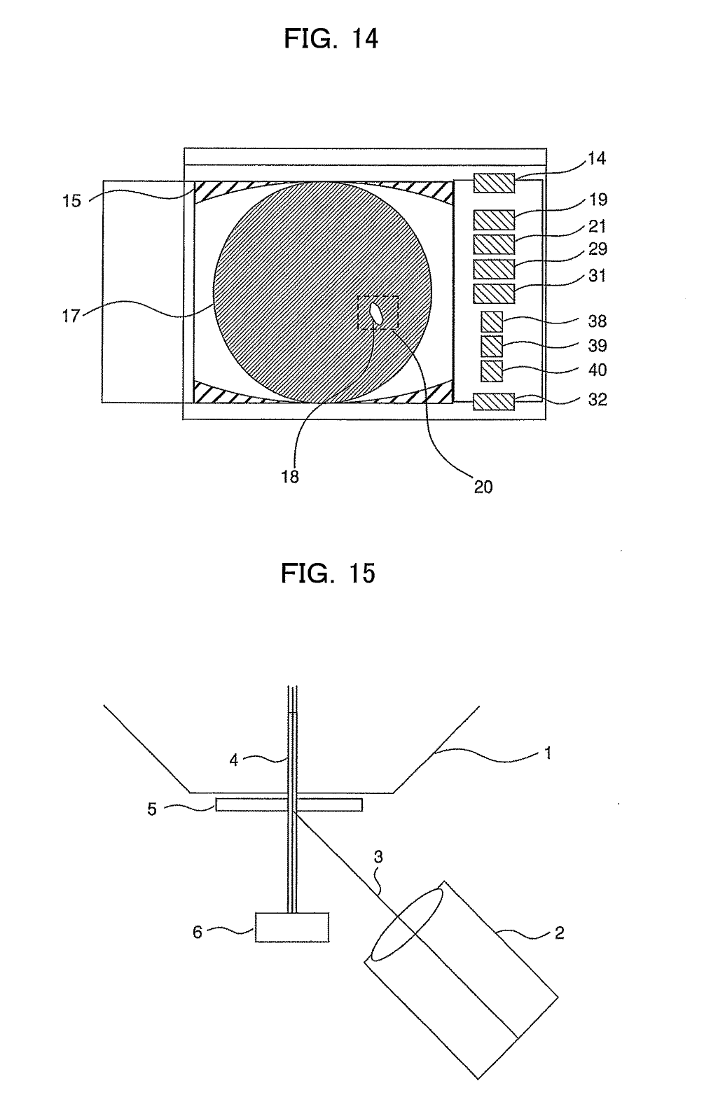

As show in FIG. 15, the manner may be adopted in such a way that a mirror and backscattered electron detector is located directly below the objective lens of the electron microscope, and an optical image imaging device including a digital picture function and an illumination function coaxial with the optical axis is located diagonally below the mirror and backscattered electron detector. In the same as the embodiment 5, the present embodiment has the electron microscope having components other than the construction as shown in FIG. 11, which are the same as those in FIG. 3. The mirror and backscattered electron detector 5 is desirably a semiconductor backscattered electron detector having the detection surface for reflection electron composed of a mirror surface, and vapor deposition with aluminum may be applied to the detection surface to increase reflection efficiency of visual light. The mirror and backscattered electron detector has an aperture at the central portion, through which an electron beam radiated on a sample on the specimen holder 6. The mirror and backscattered electron detector has desirably a diameter of 30 mm or more, however the diameter is not limited to this. The aperture at the central portion of the mirror and backscattered electron detector has desirably a diameter of 5 mm or less.

The optical axis 3 of the optical image imaging device and the mirror surface 5 of the mirror and backscattered electron detector have an angle of 45 degree therebetween. The optical axis 4 and the mirror surface of the mirror and backscattered electron detector have an angle of 90 degree therebetween. However, the angle of the optical axis of the optical image imaging device and the mirror surface of the mirror and backscattered electron detector is not limited to 45 degree.

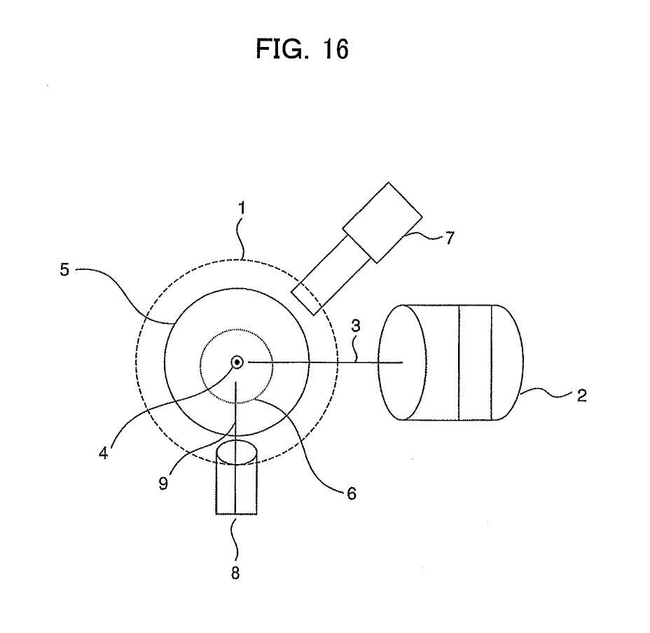

FIG. 16 is an explanation view showing the embodiment from the upper, in which the mirror and backscattered electron detector is located directly below the objective lens of the electron microscope and the optical image imaging device is located diagonally below the mirror and backscattered electron detector.

In the embodiment, a distortion occurs on the aspect ratio of a specimen holder which is projected on the mirror and backscattered electron detector as viewed from the optical image imaging device. This distortion is enabled to be solved by adequately adjusting the aspect ratio by the image processing. A method for adjusting the aspect ratio may be by mathematically calculating from the positional relationship between the specimen, the mirror and backscattered electron detector and, in addition, the optical image imaging device. Calibration may be performed by displaying a specimen, having a previously known aspect ratio, on a window and by changing an aspect ratio of a specimen transited to the window into the previously known aspect ratio. The specific operational procedure is the same as those of the embodiments 1, 2, 3 and 4.

### EXPLANATION OF REFERENCE SIGNS

1 electron microscope objective lens

2 optical image imaging device

3 optical axis of optical image imaging device

4 optical axis of electron microscope

5 mirror and backscattered electron detector

6 specimen holder

7 energy dispersive X-ray spectroscopy

8 illumination device for obtaining shaded image

9 optical axis of illumination device for obtaining shaded image

10 sample on specimen holder

11 outline of specimen holder reflected by mirror and backscattered electron detector

12 sample on specimen holder reflected by mirror and backscattered electron detector

13 aperture at the center of mirror and backscattered electron detector

14 start button

15 optical image displayed on image window

16 digital processing for covering aperture at the center of mirror and backscattered electron detector

17 image of entire top surface of specimen holder

18 optical image of sample on specimen holder

19 visual field moving button

20 capture position selection tool

21 capture position decision button

22 composite image of electron microscope image and optical image

23 scale bar

24 opacity setting bar

25 small sized image switch button

26 live image switch button

27 electron microscope image

28 optical image

29 save button for composite image

30 reset button

31 save button for electron microscope image

32 alignment button

33 input tool for specimen holder size

34 specimen holder setting frame for alignment

35 alignment completion button

36 optical image of foreign matter

37 electron microscope of foreign matter

38 foreign matter mode button

39 display button for energy-dispersive X-ray spectrometry result

40 mapping start button

301 electron optical lens barrel

302 vacuum specimen chamber

303 evacuation device

304 personal computer

1. An electron microscope including an electron optical lens barrel for scanning an electron beam on an observation specimen; and a vacuum specimen chamber holding a specimen holder having the observation specimen placed thereon,
the electron microscope characterized by
an optical image imaging device held in the vacuum specimen chamber; and
a backscattered electron detector provided on an optical path joining on the observation specimen from the optical image imaging device,
the backscattered electron detector having a reflection electron detection surface composed of a mirror surface.

2. The electron microscope according to claim 1,
wherein an optical axis of the optical image imaging device and the mirror surface of the backscattered electron detector have an angle of 45 degree therebetween,
wherein an optical axis of an electron beam and the mirror surface of the backscattered electron detector have an angle of 45 degree therebetween.

3. The electron microscope according to claim 1,
wherein the backscattered electron detector is located to be horizontally offset from position being directly below an objective lens of an electron microscope.

4. The electron microscope according to claim 1,
wherein the optical image imaging device is located diagonally below the backscattered electron detector.

5. The electron microscope according to claim 1, further comprising image processing means for performing a processing of reducing opacity of an optical image obtained, by performing an image processing of superimposing the optical image on an electron microscope image obtained.

6. The electron microscope according to claim 5,
wherein the image processing means sets opacity of the optical image to 75% or 45%.
